(19) United States
(12) Patent Application Publication
(10) Pub. No.: US 2023/0323529 A1
(43) Pub. Date: Oct. 12, 2023

(54) METHOD AND DEVICE FOR THE OUTER-WALL AND/OR INNER-WALL COATING OF HOLLOW BODIES

(71) Applicant: RHEINISCH-WESTFÄLISCHE TECHNISCHE HOCHSCHULE (RWTH) AACHEN KÖRPERSCHAFT DES ÖFFENTLICHEN RECHTS, Aachen (DE)

(72) Inventor: Montgomery JARITZ, Aachen (DE)

(21) Appl. No.: 18/016,328

(22) PCT Filed: Jul. 9, 2021
(86) PCT No.: PCT/EP2021/069135

§ 371 Date: Jan. 13, 2023

(30) Foreign Application Priority Data
Jul. 15, 2020 (DE) 10 2020 118 718.1

(51) Int. Cl. C23C 16/04; C23C 16/511; C23C 16/52; C23C 16/40; H01J 37/32

(52) U.S. Cl. CPC C23C 16/045; C23C 16/511; C23C 16/52; C23C 16/401; H01J 37/32816; H01J 37/3266; H01J 37/32935; H01J 2237/1825; H01J 37/32192; H01J 2237/24578

(57) ABSTRACT

Apparatus and method for outer wall and/or inner wall coating of hollow bodies made of an electrically nonconductive material in which the hollow body is inserted into a process chamber which is divided by the hollow body into an internal and external reaction space, wherein at least one process gas is introduced into one of the two reaction spaces under a process pressure, and a plasma is generated in the reaction space and fragments and/or reaction products formed in the plasma from the at least one process gas are deposited to form a layer on the side of the wall of the hollow body that faces the plasma, the plasma being influenced with regard to at least one operating parameter by a magnetic field that permeates the two reaction spaces.

The invention relates to a method of outer wall and/or inner wall coating of hollow bodies made of an electrically nonconductive material, especially of plastic bottles or canisters, preferably made of PE (HD-PE, LD-PE), PET, PP, PC or PLA, in which the hollow body is inserted into a process chamber which is divided by the hollow body into an internal and external reaction space, wherein at least one process gas is introduced into one of the two reaction spaces under a process pressure, while the other of the two reaction spaces is being kept at a pressure of less than or greater than the process pressure, and wherein a plasma is generated in the reaction space which is kept under process pressure and fragments and/or reaction products formed in the plasma from the at least one process gas are deposited to form a layer on the side of the wall of the hollow body that faces the plasma.

The invention further relates to an apparatus for outer wall and/or inner wall coating of hollow bodies made of an electrically nonconductive material, especially of plastic bottles or canisters, comprising a process chamber into which the hollow body can be inserted and which is divided by the hollow body inserted into an internal and an external reaction space, at least one vacuum pump with which the reaction spaces are evacuable, especially electively, at least one process gas feed by means of which the at least one process gas can be introduced, especially electively, into one of the reaction spaces, especially by means of which a process pressure can be established in one of the two reaction spaces with the at least one process gas in conjunction with the at least one vacuum pump, at least one energy generation unit, especially at least one microwave generator, with which energy can be introduced, especially electively, into one of the two reaction spaces for generation of a plasma. Preferably, the energy for ignition of the plasma is introduced from a reaction space in which no plasma is ignited through the hollow body into the reaction space in which the plasma is to be ignited. For this purpose, the reaction space through which the energy passes is kept at a pressure lower than the process pressure.

Such an apparatus is utilizable in order to alternatively provide the inner wall or the outer wall or both sequentially and successively with a layer, especially in order to deposit, in the form of the layer, a diffusion barrier or else other functional layer on the respective wall from at least one process gas comprising precursors on a respective wall.

For example, the process gas utilized may be a gas containing gaseous monomers. One example of a known procedure is to deposit SiOₓ as diffusion barrier on a hollow body, for example bottles, from a process gas mixture including hexamethyldisiloxane (HMDSO) and oxygen as precursors. The invention preferably likewise makes use of this application, but is not limited thereto. Other process gases are, for example, hexamethyldisilazane (HMDSN), silane (SiH₄), ethyne (C₂H₂), methane (CH₄), difluoroethylene (C₂H₂F₂) or the like.

For this purpose, in the reaction space containing the process gas or into which the process gas is fed, a process pressure is generated, which is lower than the surrounding atmospheric pressure, in order to create conditions for a plasma. In particular, this process pressure is in the range from 10 Pa to 30 Pa. In the reaction space having the process gas under the process pressure, a plasma is generated by incident energy, e.g. microwave radiation, which is generated by the energy generation unit. The plasma fragments the at least one process gas. The fragments and/or reaction products formed from the fragments are deposited as a layer on the wall of the hollow body that faces the plasma. In order to avoid plasma ignition in the other reaction space, it is evacuated, for example, to a pressure lower than the process pressure. For example, this pressure is less than 10 Pa, preferably not more than 5 Pa. Alternatively, the reaction space in which no plasma is to ignite is kept at a pressure greater than the process pressure, for example at the surrounding atmospheric pressure.

The energy is supplied by incidence of microwaves into the reaction space comprising the process gas, preferably through the other reaction space. The procedure in the invention is preferably the same, but is not limited thereto. In general, it is possible to generate any electromagnetic radiation by means of at least one signal generator in the energy generation unit that generates radiation with a frequency suitable for ignition of the plasma with the chosen process gas. The radiation may preferably be matched to absorption bands of the process gas used. Further preferably, the incident radiation may be pulsed. Any signal generator used, especially one each for inner and outer coating, may be executed as a module in which the components for generation and incidence of the electromagnetic radiation are combined, with each module being disposed exclusively in the reaction space in which no plasma ignites. A respective signal generator can generate electromagnetic waves in the microwave band and/or HF band.

Several problems can arise in association with the method mentioned and the known apparatus. In the case of comparatively large hollow bodies, for example having a volume of greater than 5 liters, a large extent of the plasma is required. Specifically in the case of microwave excitation of the plasma, which is used with preference, there may be minima and maxima in the microwave intensity in the reaction space and local absorption of the microwave energy, which can lead to inhomogeneous plasma, which then gives rise to nonuniform layers.

The large extents of the plasma also result in a high energy demand in order to generate a sufficient energy density throughout the plasma. This is of relevance firstly in the case of large hollow bodies and secondly in the case of external coatings, since the plasma here is restricted not by the internal volume of the hollow body, but by the process chamber that surrounds the hollow body, which is necessarily always larger than the hollow body.

In addition, it is problematic in the case of outer coatings that, as well as the outer wall of the hollow body to be coated, the interior of the process chamber is always also coated. Continuous performance of such a coating process is thus not possible to date without interruptions for cleaning. Furthermore, the concomitant coating of the process chamber elements leads to a change in process parameters, for example with regard to transparency to microwave radiation, such that these have to be adjusted in the course of the process procedure in order to assure constant quality of the layers.

Although mainly inner coatings of hollow bodies, for example PET bottles, have become established in Europe for particular applications, for example in the chemical industry, the achievable barriers are too low in some cases. In plasma-polymeric barrier layers, intrinsic stresses develop during the layer growth process with rising thickness, which lead to cracks in the layer over and above a particular layer thickness. An increase in the barrier performance by a rise in layer thickness is thus impossible. In addition, depending on the deposition conditions, open pores are formed in the layers, which can adversely affect the barrier.

An improvement in the barrier already becomes possible via a correct process design in respect of plasma homogeneity and via deposition of a multilayer system composed, for example, of alternating organosilicon (SiOCH)- and silicon oxide (SiOₓ) coatings. Since SiOCH layers develop intrinsic tensile stresses and SiOₓ layers develop compressive stresses, the layer stress of the overall system can be reduced and hence the layer thickness and permeation barrier can be increased. The result is an extension of the permeation pathways since pores in the individual layers of a multilayer system are only unlikely to lie directly one on top of another. However, it is also sufficiently well known that the increasing of the number of layers likewise does not result in a linear increase in the barrier. One reason for this is that the evolution of layer stress in the layer system can be restricted only in part. Secondly, defects and pores in the layers propagate into the next layer in spite of an interlayer. The latter can be overcome only by applying the coating from both sides. For instance, it is possible by coating on both sides to reduce the transmission of gases through the system almost to zero. This is attractive particularly for companies in the chemical industry. For example, in the agrochemical sector, it is common to use packaging consisting of multiple different plastics, each of which has a function (for example barrier against water, barrier against gases, etc.). Such composites cannot be economically separated from one another, such that the resultant post-consumer wastes can often only be incinerated. Plasma-polymeric high barrier coatings can solve this problem and enable recyclable containers having high barrier properties.

It is thus an object of the invention to provide a method and an apparatus of the type specified at the outset, with which homogeneous inner coatings and outer coatings are achievable with avoidance or at least with reduction of the concomitant coating of the process chamber, and preferably with which, irrespective of the coating side, comparatively large hollow bodies are also coatable in a high-quality manner, especially those with volumes greater than 5 liters, preferably greater than 50 liters, further preferably greater than 100 liters, even further preferably at least up to 200 liters.

One way of achieving this object in the method specified at the outset is by influencing the plasma with regard to at least one operating parameter by means of a magnetic field that permeates the process chamber, especially the two reaction spaces.

In the apparatus, the object is achieved in that it comprises at least one element with which a magnetic field that permeates the process chamber can be generated, especially in order to influence the plasma that can be generated with regard to at least one parameter of the plasma.

The at least one element with which a magnetic field that permeates the process chamber can be generated is preferably at least one element which is provided in addition to the energy generation unit and/or in addition to apparatuses that interact in plasma generation with the energy generation unit, with which the plasma is generated. For instance, specifically in the case of preferable use of microwaves for plasma generation, it may be the case that the microwaves generate electromagnetic radiation with which a magnetic field that fluctuates with time, especially fluctuates with time with the frequency of the microwaves, is generated. In such a case, the invention accordingly envisages that the magnetic field for influencing the plasma that permeates the process chamber is different, or is generated with different apparatuses, than any magnetic field present with which the plasma is generated. The magnetic field that influences the plasma in the process chamber may thus be adjusted and/or altered separately from the plasma generation in order thus to enable influencing of the plasma generated.

The magnetic field with which the plasma is influenced may preferably be static with time, preferably at least during the existence of a plasma, or if it changes over time, may have a lower frequency of change over time compared to the plasma-generating magnetic field.

The invention here makes use of the fact that the ions of the fragments and/or reactive products of the one or more process gases that are present in the plasma can be deflected by means of a magnetic field, and can especially thus also be influenced. It is thus possible to exert an influence on the plasma with regard to one or else more than one parameter by means of a magnetic field that permeates the process chamber during the performance of the method and hence likewise permeates the two reaction spaces, especially those in which the plasma is present.

For instance, the magnetic field, by virtue of the Lorentz force, brings about acceleration of the ions along the magnetic field lines. This leads to spatial homogenization of the plasma, which is especially understood to mean that greater homogeneity is achieved under the action of the magnetic field compared to a plasma without an active magnetic field. For example, homogeneity may be considered at a constant distance along the wall of the hollow body to be coated. This effect is advantageous particularly in the case of comparatively large hollow bodies.

Preferably, the magnetic field may be chosen such that, in a given longitudinal direction of the hollow body, in which it thus has its greatest extent, the field lines run predominantly in this longitudinal direction. This can be achieved, for example, when the poles of the magnetic field generated are spaced apart in this longitudinal direction. The elements that generate the magnetic field may accordingly be positioned in the apparatus in order to achieve this.

The invention may further envisage increasing the energy density of the plasma by means of the magnetic field, especially wherein a greater energy density is achieved under the action of the magnetic field compared to a plasma without an active magnetic field. For instance, in the case of comparatively large hollow bodies, it is possible to reduce the energy demand.

As a further parameter, the magnetic field can influence the spatial position of the plasma. This is preferably effected in such a way that the plasma, by virtue of the action of the magnetic field, is kept at a greater distance from the process chamber wall and/or elements in the process chamber compared to the distance that would exist without an active magnetic field. For instance, this specifically leads to the effect that the plasma is restricted to a region directly around the hollow body to be coated.

The plasma thus lies closer to the hollow body compared to the plasma without magnetic field. The action of the magnetic field can thus reduce or advantageously entirely prevent concomitant coating of the process chamber or of elements in the process chamber, particularly in the case of layer depositions on the outer wall of the hollow body. As a result, outer wall coating can be conducted in a much more economically viable manner than has been possible to date.

Especially in conjunction with the influencing of the local position of the plasma by the magnetic field, it may be the case that at least one sensor, preferably optical sensor, especially a camera, is used in the apparatus or in the method, with which the spatial position of the plasma generated is detected, preferably contactlessly, especially during the influencing by the magnetic field, especially while the influence by the magnetic field is being detected, and the at least one magnetic field-generating element is actuated depending on the data detected by the at least one sensor, especially in order to influence or to alter the magnetic field depending on these data. For example, it is possible to implement such a system of closed-loop control which keeps the plasma at a predetermined minimum distance or within a predetermined margin from the wall of the hollow body to be coated and/or from the process chamber wall.

In the plastic packaging industry, a multitude of containers having different volumes and in some cases complex geometries are used. The plasma process for coating of the containers with a functional layer is preferably adapted correspondingly according to the invention to the respective container, especially in order to be able to assure homogeneous coating with desired functionality. At the same time, the invention can offer high flexibility of the coating system with regard to the container sizes and geometries to be coated.

By virtue of the use of magnetic fields designed in accordance with the containers, it is possible to adjust the plasma flexibly to the geometry of the container, both in the internal and external coating.

In a further possible execution of the invention, it may be the case that the extent and intensity of the plasma influenced by the magnetic field lines is detected by the aforementioned at least one optical sensor, preferably an imaging sensor, for example a CCD or infrared camera system, and feedback of these data to the coil system is undertaken.

By supplying different power to the coils for generation of the magnetic field depending on the evaluation of the spatial extent of the plasma within and/or outside a container by means of the at least one sensor, it is possible to adjust and calibrate the magnetic field and hence the plasma in a flexible manner to any container geometry and size during the process.

The magnetic field-generating element used may preferably be a coil. This has the advantage of directly influencing the magnetic field strength via the current. Plasma parameters can thus be altered by changing the power supplied. The power supplied can preferably be chosen depending on the shape and/or size of the hollow body to be coated. For instance, the apparatus or method may be adjusted individually to the hollow body.

In a preferred execution, the invention may provide for generation of the active magnetic field by superimposition of the magnetic fields from multiple magnetic field-generating elements, especially multiple coils.

For example, it is possible in this way to adjust the profile of the magnetic field lines of the active magnetic field at least in regions to the profile of the wall to be coated in the hollow body, especially by means of actuation of the magnetic field-generating elements depending on the hollow body shape, especially by powering of the coils depending on the hollow body shape.

In general, the invention may comprise multiple elements with which a magnetic field that permeates the process chamber can be brought about by superimposition of the magnetic fields generated by the respective elements. The at least one element may advantageously take the form of a coil that can be supplied with power.

It may also be the case that multiple elements may be formed by a first number of permanent magnets and a second number of coils, the magnetic fields of which overlap. Variation of the magnetic field, for example for alteration of plasma parameters, may thus be generated by varying the power supply to the coil, especially wherein the permanent magnets can generate a base magnetic field strength about which variation is possible.

In one possible execution, it may be the case that multiple coils for generation of a superimposed magnetic field are arranged in succession in a direction of axial extent of the process chamber, especially that corresponding to the longitudinal direction of a hollow body to be coated. As mentioned at the outset, it is thus possible to place the direction of spacing of the poles in the direction of longitudinal extent.

In this context, in one development of the invention, it may be the case that at least one of the coils is disposed at an axial end of the process chamber, especially at the opposite end from axial end face of a hollow body, and has a shorter winding diameter than the other coils, especially those which are disposed on the outside of the process chamber, or in the case of an arrangement within the process chamber surround the outside of a hollow body that can be inserted into it. By means of coils disposed at the axial end, it is possible to generate the effect of a magnetic mirror, by means of which the plasma can be restricted to the axial length of the hollow body, and in this case can especially be kept at a distance from the axial process chamber walls.

At least one of multiple coils or the sole coil for radial restriction of the plasma is preferably disposed on the outside of the process chamber wall. In particular, this is possible and preferred in the case of a nonmetallic design of the process chamber wall, for example made of glass, preferably borosilicate glass or quartz glass. Coils at the axial end, at the opposite end from the axial end face of a hollow body, may be disposed within or outside the process chamber. This is especially dependent on the choice of material for the axial process chamber wall.

In one execution of the invention, it may further the case that at least one energy transfer element, especially at least one hollow conductor, by means of which energy can be introduced into the process chamber, is disposed in an axial margin between different axially adjacent coils or between axially adjacent winding sections of the same coil. Thus, in this way, the energy can be introduced through the coil arrangement.

In a preferred embodiment, it may also be the case in the invention that multiple elements that generate the influencing magnetic field are designed such that they comprise or form at least two groups of coils that can be supplied with power, with each of which a plasma-influencing magnetic field can be generated, or is generated in the method, especially for each group independently and/or else depending on another group. It may be the case that the at least two groups are used to generate the plasma-influencing, especially in each case the same plasma-influencing, magnetic field successively in time, especially for successive coating cycles on different hollow bodies or for one coating cycle on the same hollow body, especially with a temporary overlap of the power supply to the two groups. For such sequential power supply to the groups, the apparatus may comprise a control unit set up for corresponding power supply.

Preferably, each group has at least one coil that can be supplied with power, preferably multiple coils that can be supplied with power, which may especially have one of the aforementioned arrangements, i.e. may especially comprise coils that restrict the magnetic field radially with regard to the longitudinal container axis and/or restrict it axially, preferably in the manner of the aforementioned magnetic mirror.

In particular, it may be the case that each group of coils generates at least essentially the same magnetic field configuration or magnetic field geometry, especially respectively forms what is called a magnetic bottle. The magnetic bottles of all groups are preferably identical, especially during plasma production in a respective at least temporarily static case.

In particular, the same magnetic field configuration/geometry is understood to mean that the magnetic fields that are generated by the groups each have the same field strength locally in the process chamber, especially with an at least essentially identical field line progression.

In one group, it is also possible to combine coils and permanent magnets in order to generate the magnetic field, especially as described above. The invention preferably includes the coating of hollow bodies on the inside and/or outside having a volume of 0.2-500 I, preferably of 1-100 I and further preferably of 5-30 liters.

In order to build up the required magnetic flux density for influencing the plasma, in the case of high-volume hollow bodies, especially of the abovementioned volumes, correspondingly large coils are required, through which a few amperes of current must flow depending on the number of windings.

The electrical power introduced may be higher in the coils than the loss of heat energy via convection and radiation, such that there can be significant heating of the coils in sustained operation. In this case, the invention may envisage assigning at least one cooling system to the coils.

In a preferred execution, the invention may alternatively envisage, especially for avoidance of a cooling system, sequential switching and power supply to groups of the aforementioned type or a power supply strategy in order to reduce the heating of coils, which especially makes it possible to manage without additional cooling of the coils. One aim of the invention is preferably to maintain an average temperature of the coils in the sustained stability range of the coil material by allowing sufficiently long cooling times for the coils or groups in each case. This can be effected in that, when power is being supplied to one group for generation of the influencing magnetic field, at least one other group can cool down.

In order to be able to ensure sustained stability of the coils, these should preferably not become hotter than 90° C., or the current through these should not exceed a value of about 2.5 A/mm², especially not on average over time.

Means of implementing sequential switching off groups and/or a power supply strategy are discussed hereinafter in the working example.

A working example of the invention is elucidated by the figures that follow.

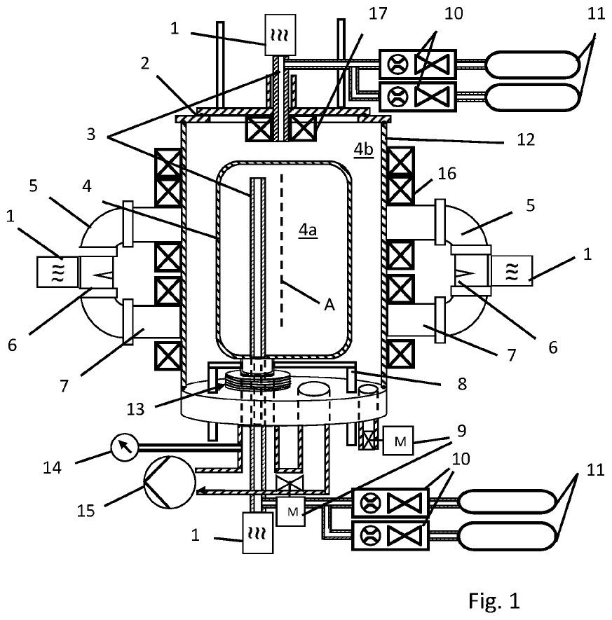

The apparatus of the invention as shown in FIG. 1 permits application of a sequential, and in each case exclusive, inner and/or outer coating to a hollow body 4 made of plastic, for example to large-volume containers 4 made of plastic. For generation of a layer, at least one process gas is introduced into the respective reaction space 4a or 4b via one of the respective hollow antennas 3 and excited to a plasma, which generates plasma polymerization. The reaction space 4a is defined here by the interior of the hollow body 4. The reaction space 4b by the space between the outer wall of the hollow body 4 and the process chamber 12.

The coating process overall is effected under low pressure, i.e. a pressure lower than the surrounding atmospheric pressure. The necessary pressure may be generated by means of a vacuum pump 15 for each of the two reaction spaces 4a/4b. The ignition of the plasma is generated with pulsed microwave excitation which is generated by the signal generators 1 and released via hollow antennas 3 and/or hollow conductors 5. According to the invention, the plasma here is influenced by a magnetic field which is generated by the coils 13, 16 and 17 that are supplied with power.

In the method, the hollow body 4 is fixed in a gas-tight manner in the process chamber 12. Once the process chamber has been closed, by way of example for the outer coating, process gases are first introduced into the outer reaction space 4b via a gas probe 3 in the reactor lid 2, which is simultaneously a microwave antenna for the inner coating, and a process pressure of, for example, 10 to 30 Pa is established.

The inner reaction space 4a of the container 4 here preferably remains under atmospheric pressure or close to atmospheric pressure. Microwave radiation is introduced into the process chamber 12 via an antenna 3, especially matched to the container geometry, which is especially also a gas probe for the inner coating. The radiation passes through the inner reaction space 4a of the hollow body 4 virtually without loss. The significantly higher pressure in the inner reaction space 4a here prevents the ignition of a plasma. The microwave radiation reaches the outer reaction space 4b of the hollow body 4, where it encounters suitable conditions for a plasma state, as a result of which the deposition process is initiated on the outer wall of the hollow body 4.

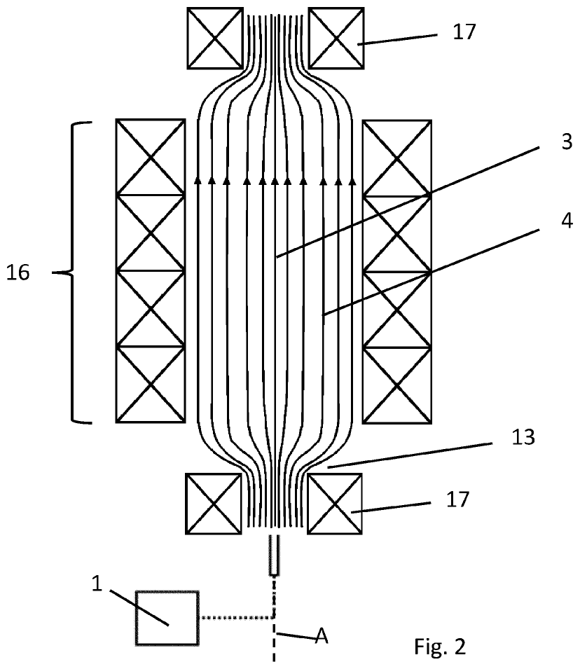

At the same time, a magnetic field is generated by means of a coil arrangement composed of coils 16 and 17, which homogenizes the plasma along the field lines by means of the acceleration generated in the charged particles and simultaneously keeps it away from the chamber walls of the process chamber 12 by means of a magnetic enclosure. In FIG. 1, based on the longitudinal axis A of the hollow body 4, an axially terminal coil 17 which is at the opposite end from the upper axial end wall of the hollow body 4 and has a smaller diameter than the coil 16 is provided, which creates a constriction of the field lines at the axial end, and hence the effect of a magnetic mirror for the plasma. Such a coil 17 is disposed here only at an axial end, the upper end of the hollow body 4 here. It may also be the case in the invention that such a coil 17 is also provided at the other end, the lower end here, of the hollow body, especially as shown in FIG. 2.

FIG. 2 visualizes the field line profile for an execution in schematic form with coils 17 arranged at both axial ends. The field line profile of the effective magnetic field is shown and illustrates the magnetic pole spacing in the axial direction A. What is clearly apparent is the constriction of the field lines at the axial ends, which is brought about by the coils 17 having smaller winding diameter than the coils 16, which are arranged radially around the hollow body 4 based on the axis A. The field lines of the magnetic field here are forced into a bottleneck-shaped profile, especially such that the field lines are for the most part bent back together in the interior of the enclosure volume. This apparatus can be used to restrict the plasma to the direct environment of the face of the hollow body to be coated and keep it away from the process chamber walls. In addition, the plasma is homogenized and preferably compressed, which increases the energy density and hence the layer deposition rate.

The magnetic influence on the plasma is based here on the Lorentz force, which keeps the charged plasma particles, electrons and ions on screw-shaped paths in the magnetic field, and especially thereby restricts the possible local dwelling regions, homogenizes the plasma and preferably also increases the local energy density.

This magnetic enclosure, here in this example, but also with general validity for the invention, can be achieved with cylinder coils since the magnetic field of such a coil is directed parallel to the coil axis, which prevents the loss of particles in radial direction.

If an inner coating that sequentially follows the outer coating is desired, after the process of outer coating, for the subsequent inner coating, the gas supply in the outer reaction space 4b may be ended and latter may be evacuated down to a pressure level below the process pressure, preferably to about 5 Pa.

In the inner reaction space 4a of the hollow body 4, process gas is introduced via the gas probe 3 and adjusted to a process pressure, for example a pressure of about 10 to 30 Pa. Microwave radiation, which is then introduced into the process chamber 12 via the opposite antenna 3 and the laterally slotted hollow conductor 5, passes through the outer space without loss as a result of the significantly lower pressure that corresponds to an increased free path length.

The radiation in the interior 4a of the hollow body 4 then encounters suitable conditions for a plasma state, as a result of which the layer deposition process on the inner wall of the hollow body 4 is initiated. Again, the magnetic field is switched on, this time preferably solely for homogenization of the plasma, which is especially advantageous in the inner coating of large hollow bodies.

The total cycle time for the inner and outer coating, depending on the hollow body volume, is, for example, 10 to 120 seconds, especially with 1-30 seconds being required in each case for the coating. The remaining seconds are required for the evacuating and the change of sample.

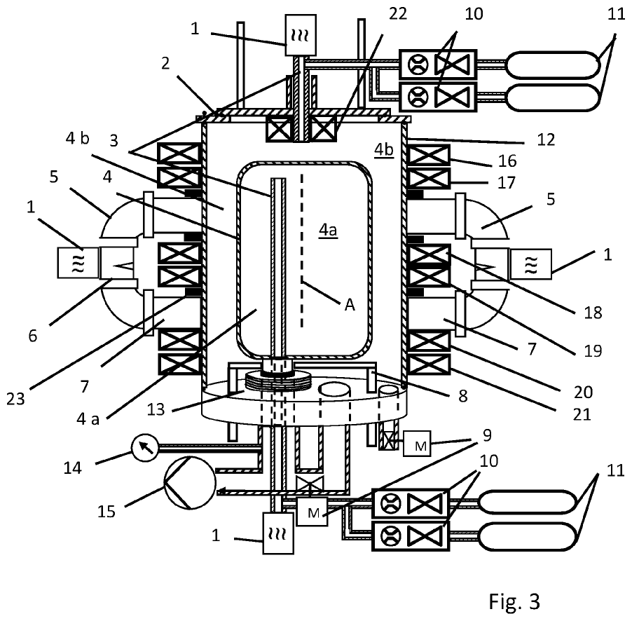

FIG. 3 shows a further working example of the invention. The cylinder coils 13 and 22 in this example, by comparison with coils 16 to 21, may be executed with a smaller diameter, and preferably with a core made of a ferromagnetic material, such that high magnetic flux densities are possible at low currents. These coils 13 and 22 are therefore less critical in relation to thermal stress.

The cylinder cons 16 to 21 by contrast, for process- and system-related reasons, have a greater inner radius (especially corresponding to or larger than the outer radius of the process chamber 12) and, in this execution, preferably do not have a core.

In an alternative execution, the antenna/gas probe 3 may preferably be formed from a ferromagnetic material in order to achieve an increase in magnetic flux density of the outer coils 16 to 21. This execution is of interest particularly for the magnetic enclosure of the plasma ignited around the outside of the container wall, i.e. in the reaction space 4b, since the field lines here run through and to the antenna 3.

The kinetic energy of the ions Eₖᵢₙ in a microwave plasma may typically assume values of up to 30 eV or 4.8E-18 J and is dependent on the coating process and system type. In order to steer these charged particles with a magnetic field, depending on Eₖᵢₙ, a magnetic flux density of up to 0.01 T to 1 T is required. The internal diameter of the process chamber 12, for a 10 L container may, by way of example, be about 350 mm. With a cylinder coil having this internal diameter, preferably without a core, and having 5000 windings, for example, and a power supply of 3 A, it is possible to achieve, by way of example, a magnetic flux density of about 0.05 T. The strength of this magnetic field can also be enhanced by the coils 13 and 22 depending on the power required. In this example, the coil, with inclusion of energy loss via convection (laminar flow at v=2 m/s), achieves a temperature of 90° C., for example, which is critical for sustained stability after about 30 seconds. After the coil has been switched off, a few minutes may be required until it has sufficiently cooled down again. There are various options for taking account of the cooling times of the coils in the process. Possible use examples are:
1. Different Groups of Coils are Used in Each Coating Cycle

Loading and removal operations, vacuum generation and introduction of gas are preferably included in the total cycle time, such that this is fixed depending on the vessel size and may, for example, be 10 s to 120 s. In each coating operation, only the coils of a particular group of coils are switched on in order to generate the plasma-influencing magnetic field, such that the coils of at least one other group of coils, especially the coils used previously, can cool down. For example, it would be possible in the first coating process first to use coils 16, 18 and 20 of a first group and then, in the subsequent process, coils 17, 19 and 21 of another group. In this way, it is possible in each case to generate a uniform magnetic field, especially in each case an at least essentially identical magnetic field, and the coils in the groups undergo sufficient cooling to be reused in the subsequent process.
2. The Groups of Coils are Switched on and off in Alternation Within a Coating Cycle

In this case in particular, processes of coil charging and discharging should be noted. A current accentuated by induction will always act against the cause of its formation (change in magnetic field). During the charging operation, the flow of current is inhibited by the self-induced voltage of the coil. The processes of coil charging and discharging may, depending on their configuration size, last for a few milliseconds, but also a few tens of seconds. Taking account of these charging and discharging processes, groups of coils are alternately supplied with current during the coating process, especially such that a sufficiently high average magnetic flux density is achieved at sufficiently low maximum operating temperature. The inductivities can be taken into account via a mutually adjusted increase in current over time in one group, while the current is reduced in another group, until one group has displaced the other group for generation of the magnetic field. It is preferably ensured here that the superimposed magnetic fields of the two groups, at the times when two groups are simultaneously supplied with current, correspond to the magnetic field that each group also generates on its own after the other has been switched off.

Thus, both in the case of sole operation of one group and during the time interval of switchover of operation from one group to another, the same magnetic field is generated.

FIG. 3 additionally shows, by reference numeral 23, an optical sensor for detection of the plasma during operation, in order to regulate this using the sensor measurements, especially with regard to the plasma position or the distance between plasma and process chamber wall or plasma and hollow body wall.

### LIST OF REFERENCE NUMERALS

1.) Signal generator

2.) Lid of the process chamber, especially movable by guide rod (e.g. pneumatically driven)

3.) Gas probe/antenna (electively made of ferromagnetic material)

4.) Hollow body

5.) Hollow conductor arc

6.) Energy distribution

7.) Hollow conductor

8.) Guide rod made, for example, of PEEK or similar materials that have high transparency to microwaves and magnetic fields

9.) Valve

10.) Gas flow regulator

11.) Gas reservoir

12.) Process chamber, for example with radial wall of borosilicate glass or similar materials that have high transparency to microwaves and magnetic fields

13.) Base of process chamber with sealing surface for accommodation of the hollow body, and optionally coil with core of ferromagnetic material for magnetic mirror action at the axial end

14.) Pressure measurement

15.) Pump stand with at least one vacuum pump

16.) Coil for generation of a magnetic field

17.) Coil for generation of a magnetic field

18.) Coil for generation of a magnetic field

19.) Coil for generation of a magnetic field

20.) Coil for generation of a magnetic field

21.) Coil for generation of a magnetic field

22.) Coil for generation of a magnetic field, especially with core of ferromagnetic material, for magnetic mirror action at the axial end of the hollow body

23.) Sensor for detection of the spatial spread of the plasma

1. A method of outer wall and/or inner wall coating of a hollow body made of an electrically nonconductive material, comprising inserting the hollow body into a process chamber which is divided by the hollow body into an internal reaction space and an external reaction space, introducing at least one process gas into one of the two reaction spaces under a process pressure while the other of the two reaction spaces is being kept at a pressure of less than or greater than the process pressure, and generating a plasma in the reaction space into which the process gas has been introduced while keeping that reaction space under process pressure, whereby fragments and/or reaction products formed in the plasma from the at least one process gas are deposited to form a layer on the side of the wall of the hollow body that faces the plasma, wherein the plasma is influenced with regard to at least one operating parameter by means of an active magnetic field that permeates the two reaction spaces.

2. The method as claimed in claim 1, wherein a parameter influenced by the active magnetic field is at least one of the following:
a. homogeneity of the plasma viewed at a constant distance along the wall of the hollow body to be coated, where greater homogeneity under the action of the active magnetic field is achieved compared to a plasma without an active magnetic field,
b. energy density of the plasma where a greater energy density is achieved under the action of the active magnetic field compared to a plasma without an active magnetic field,
c. spatial position of the plasma where the plasma, by the action of the active magnetic field, is kept at a greater distance from a wall of the process chamber and/or elements in the process chamber compared to the distance without an active magnetic field.

3. The method as claimed in claim 2, wherein the active magnetic field is generated by superimposition of the magnetic fields of multiple magnetic field-generating elements comprising multiple coils or permanent magnets.

4. The method as claimed in claim 3, wherein magnetic field lines of the active magnetic field, by powering of the coils in a manner dependent on the hollow body shape, are matched in terms of their profile at least in regions to the profile of the wall of the hollow body to be coated.

5. The method as claimed in claim 3, wherein at least two groups of the coils are used successively in time to generate the same plasma-influencing magnetic field with a temporary overlap in the powering of the two groups.

6. The method as claimed in claim 3, wherein at least one sensor is used to contactlessly detect spatial position of the plasma generated while the influence by the magnetic field is being detected, and at least one the magnetic field-generating elements is actuated depending on the data detected by the at least one sensor in order to influence the magnetic field depending on the data.

7. An apparatus for outer wall and/or inner wall coating of a hollow body made of an electrically nonconductive material, comprising
a. a process chamber configured for insertion therein of the hollow body and which is divided by the hollow body into an internal reaction space and an external reaction space,
b. at least one vacuum pump configured to selectively evacuate the reaction spaces,
c. at least one process gas feed configured to selectively introduce at least one process gas into one of the reaction spaces by means of which a process pressure can be established in one of the reaction spaces with the at least one process gas in conjunction with the at least one vacuum pump,
d. at least one microwave generator configured to selectively introduce energy into one of the two reaction spaces for generation of a plasma, and further comprising at least one element configured to generate a magnetic field that permeates the process chamber and influences with regard to at least one parameter of the plasma.

8. The apparatus as claimed in claim 7, wherein the at least one element comprises a plurality of elements configured to generate a magnetic field that permeates the process chamber by superimposition of the magnetic fields generated by the respective elements.

9. The apparatus as claimed in claim 7, wherein the at least one element comprises a coil configured to be supplied with power or comprises a permanent magnet.

10. The apparatus as claimed in claim 9, wherein a plurality of the coils are arranged successively in a direction of axial extent of the process chamber corresponding to the longitudinal direction of the hollow body to be coated.

11. The apparatus as claimed in claim 10, wherein at least one of the coils is disposed an axial ends of the process chamber opposite from an axial end face of the hollow body to be coated, wherein the at lease one coil has a shorter winding diameter than the other coils, the other coils being disposed outside of the process chamber or being disposed within the process chamber and configured to surround the outside of the hollow body.

12. The apparatus as claimed in claim 11, wherein at least one hollow conductor configured to introduce energy into the process chamber is disposed in an axial margin between axially adjacent coils or between axially adjacent winding sections of the same coil.

13. The apparatus as claimed in claim 7, further comprising at least one sensor configured to contactlessly detect spatial position of the plasma generated while the plasma is being influenced by the magnetic field, and wherein the at least one magnetic field-generating element is configured to be actuated depending on measurements from the sensor.

14. The apparatus as claimed in claim 8, wherein the plurality of elements that generate the influencing magnetic field are configured as at least two groups of coils that can be supplied with power and each of the two groups of coils is configured to generate a same plasma-influencing magnetic field.

15. The apparatus as claimed in claim 14, further comprising a control unit configured to successively power the two groups of coils with a partial powering of two groups at the same time in a temporary overlap.
